(19) United States
(12) Patent Application Publication
(10) Pub. No.: US 2009/0001443 A1
(43) Pub. Date: Jan. 1, 2009

(54) NON-VOLATILE MEMORY CELL WITH MULTI-LAYER BLOCKING DIELECTRIC

(75) Inventors: Tejas Krishnamohan, Palo Alto, CA (US); Krishna Parat, Palo Alto, CA (US); Kyu Min, San Jose, CA (US); Rhett T. Brewer, Santa Clara, CA (US); Thomas M. Graettinger, Boise, ID (US); Nirmal Ramaswamy, Boise, ID (US); M. Noel Rocklein, Boise, ID (US)

Correspondence Address: GROSSMAN, TUCKER, PERREAULT & PFLEGER, PLLC;C/O Intellevate, LLC, P. O. BOX 52050, MINNEAPOLIS, MN, 55402, US

(73) Assignee: INTEL CORPORATION, Santa Clara, CA (US)

(21) Appl. No.: 11/771,482

(22) Filed: Jun. 29, 2007

(51) Int. Cl. H01L 29/788

(52) U.S. Cl. 257/316; 257/E29.3

(57) ABSTRACT

Disclosed is a non-volatile memory cell. The non-volatile memory cell includes a substrate having an active area. A bottom dielectric layer is disposed over the active area of the substrate which provides tunneling migration to the charge carriers towards the active area. A charge storage node is disposed above the bottom dielectric layer. Further, the non-volatile memory cell includes a plurality of top dielectric layers disposed above the charge storage node. Each of the plurality of top dielectric layers can be tuned with a set of attributes for reducing a leakage current through the plurality of top dielectric layers. Over the plurality of top dielectric layers, a control gate is disposed.

### FIELD

The present disclosure relates to a non-volatile memory cell and, more particularly, to a structure and a process of forming a non-volatile memory cell.

### BRIEF DESCRIPTION OF THE DRAWINGS

The advantages and features of the present disclosure will become better understood with reference to the following detailed description and claims taken in conjunction with the accompanying drawings, wherein like elements are identified with like symbols, and in which:

FIG. 1 is a block diagram illustrating a cross-sectional view of a non-volatile memory cell with a blocking dielectric using a plurality of top dielectric layers according to an exemplary embodiment of the present disclosure;

FIG. 2 is an energy band diagram of the blocking dielectrics in a non-volatile memory cell, according to an exemplary embodiment of the present disclosure; and

FIG. 3 is a graph illustrating a leakage current distribution with respect to the applied voltage of the blocking dielectrics in a non-volatile memory cell, according to an exemplary embodiment of the present disclosure;

Like reference numerals refer to like parts throughout the description of several views of the drawings.

### DETAILED DESCRIPTION

For a thorough understanding of the present disclosure, refer to the following detailed description, including the appended claims, in connection with the above-described drawings. Although the present disclosure is described in connection with exemplary embodiments, the disclosure is not intended to be limited to the specific forms set forth herein. It is understood that various omissions and substitutions of equivalents are contemplated as circumstances may suggest or render expedient, but these are intended to cover the application or implementation without departing from the spirit or scope of the claims of the present disclosure. Also, it is to be understood that the phraseology and terminology used herein is for the purpose of description and should not be regarded as limiting.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced item.

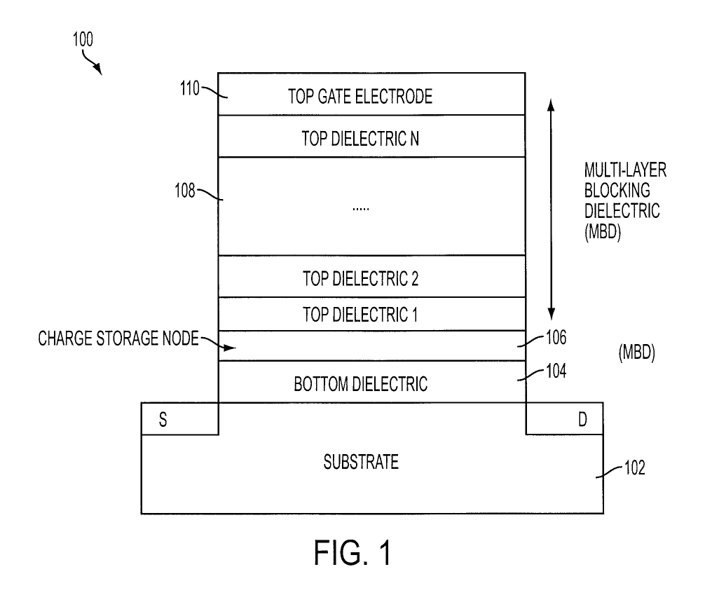

FIG. 1 is a block diagram illustrating a cross-sectional view of a non-volatile memory cell 100. The non-volatile memory cell 100 comprises a substrate 102, a bottom dielectric layer 104, a charge storage node 106, a plurality of top dielectric layers 108, and a control gate 110. The substrate 102 includes an active area on which the bottom dielectric layer 104 is disposed. The bottom dielectric layer 104 may be a single layer silicon dioxide (SiO₂), or any form of modified dielectric. In one embodiment, the bottom dielectric layer may have an equivalent oxide thickness (EOT) of less than 10 nm.

The charge storage node 106 is disposed above the bottom dielectric layer 104. The charge storage node 106 is capable of storing an electrical charge even without a power supply. In other words, the charge storage node 106 traps the electrical charges that represent Logic ‘1’ or Logic ‘0’. The charge storage node 106 may be in the form of one of a poly-silicon (poly-Si) floating gate or a charge trapping layer. As used herein, a charge trapping layer is a layer using any of or combination of traps/defects in dielectrics, doped atomic levels, metal/semiconductor clusters, metal/semiconductor sheets, metal/semiconductor nanocrystals, and the like. The charge storage node 106 has suitable attributes including, but not limited to, trap density and trap energy with an aim to produce desired program, erase and retention operation of the electrical charges. As used herein, the trap density is a parameter which denotes the ability of the charge storage node 106 to trap electrical charges.

During the program and erase operations, the bottom dielectric layer 104 provides the tunneling migration for charge carriers (of the electrical charges) between the active area of the substrate 102 and the charge storage node. These charge carriers are electrons and/or holes that need to be migrated between the charge storage node 106 and the active area during the program and erase operations in the non-volatile memory cell 100. The charge storage node 106 is surrounded by insulating layers such that the electrical charges trapped in the charge storage node 106 remains therein.

The plurality of top dielectric layers 108 is disposed above the charge storage node 106. As shown in FIG. 1, the plurality of top dielectric layers 108 includes a first top dielectric layer, a second top dielectric layer to a N^{th} top dielectric layer (N≧2 and is an integer number). Each of the plurality of top dielectric layers 108 may be tuned with a set of attributes. The set of attributes include, but are not limited to, trapping of electrical charges, an electron and hole barrier height and a dielectric constant. As used herein, the hole barrier height is defined as the difference in the valence band energies and the electron barrier height is defined as the difference in the conduction band energies.

Tuning of the top dielectric layers 108 with the set of attributes reduces the tunneling probability of the charge carriers through the top dielectric layers 108, thereby reducing a leakage current through the top dielectric layers 108. Such presence of top dielectric layers 108 (tuned with the set of attributes) in the non-volatile memory cell 100 results in a non-volatile memory cell with a multi-layer blocking dielectric.

In an embodiment of the present disclosure, each of the top dielectric layers 108 has an EOT of less than 10 nm. The overall EOT of the top dielectric layers 108 is less than 20 nm. The values of the dielectric constant for each of the top dielectric layers 108, is chosen in order to reduce the leakage current through the top dielectric layers 108. Each of the plurality of top dielectric layers 108 may be trap free and may be made of a suitable dielectric material. Suitable dielectric materials include, but are not limited to, HfO₂, SiOₓN_{y}, SiₓN_{y}, Al₂O₃, HfAlₓO_{y}, H_{f}SiₓO_{y}, ZrO₂, ZrSiₓO_{y}, La₂O₃, Y₂O₃, SiO₂, DyScₓO_{y} and LaAlₓO_{y}. Based on the above description, it will be obvious to a person skilled in the art that a desired number of top dielectric layers can be used in the non-volatile memory cell 100. The top dielectric layers 108 may be tuned with the set of attributes to reduce the leakage current through the top dielectric layers 108.

The control gate 110 is overlaid on the top dielectric layers 108. The control gate 110 can be partially or completely overlaid on the top dielectric layers 108. The control gate 108 may be made of suitable conducting materials including, but not limited to, metals, metal nitrides, silicides and doped poly-Si.

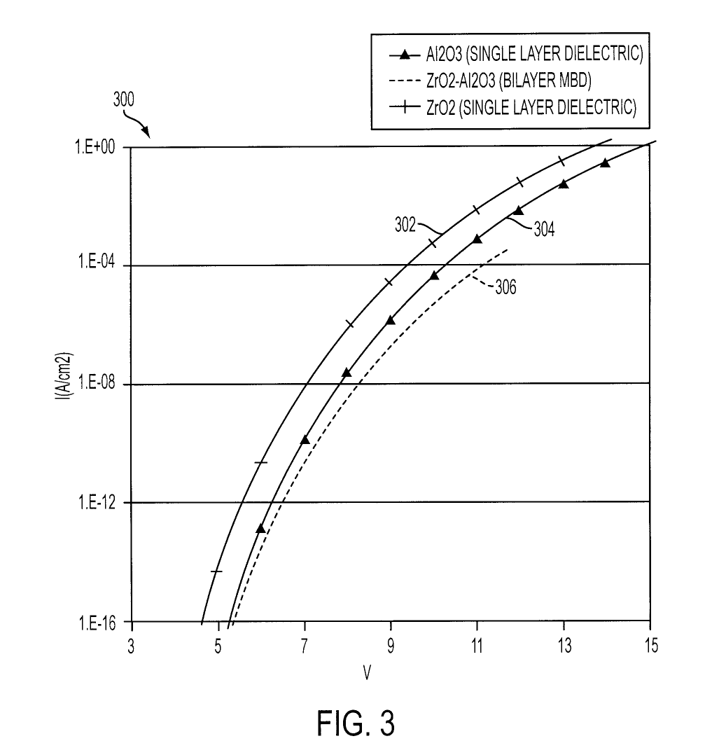

The variation of the leakage current for the various combinations of the first top dielectric layer and the second top dielectric layer for different dielectric materials is described in conjunction with FIG. 3. The reduction in the leakage allows the Non-volatile memory cell to be programmed to a higher threshold voltage. In yet another embodiment of the present disclosure, an inverted arrangement of the first top dielectric layer and the second top dielectric layer can be used in the memory cell 100. This arrangement can provide reduced leakage current through the dielectric layers under erase bias conditions, and may allow the non-volatile memory cell to be erased to a more negative threshold voltage. It will be apparent to a person skilled in the art that symmetrical tri-layered (or multi-layered) top dielectrics can be used to reduce the leakage current from the charge storage node 106 as well as control gate 110 to result in an overall larger window (i.e., a more positive program threshold voltage and a more negative erase threshold voltage).

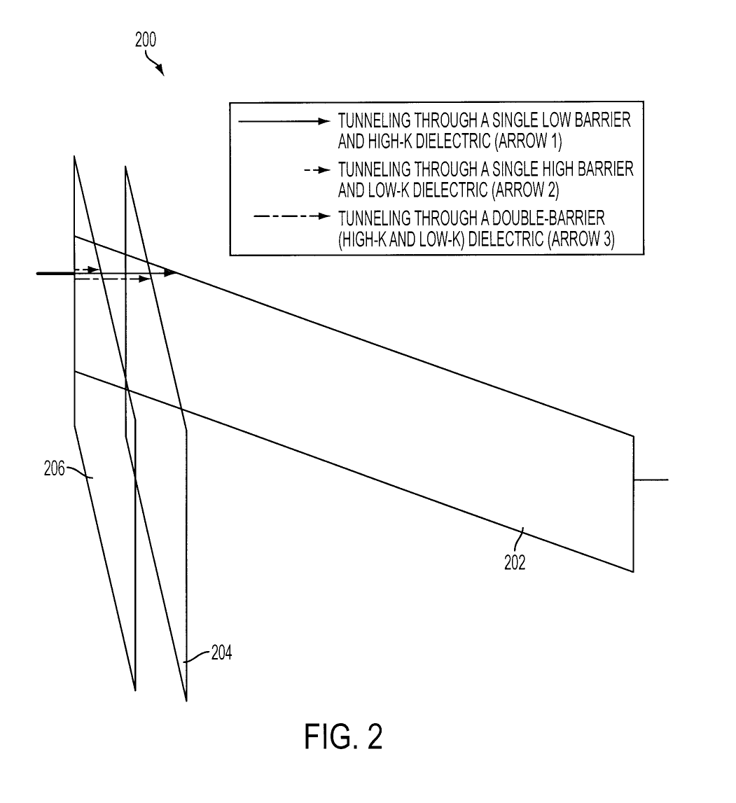

FIG. 2 is an energy band diagram 200 of the blocking dielectrics in a non-volatile memory cell 100 using a plurality of top dielectric layers 108 according to an exemplary embodiment of the present disclosure. Energy band structure 200 comprises a first energy band 202, a second energy band 204, and a third energy band 206. The energy band 202 represents energy level when the first top dielectric layer, which is of higher dielectric constant and lower barrier, is used individually to form a single top dielectric layer in the memory cell 100. Similarly, the band structure 206 represents energy level when the second top dielectric layer, which is of lower dielectric constant and higher barrier, is used individually to form a single top dielectric layer in the memory cell 100. The energy band 204 represents the energy level when the first top dielectric layer and the second top dielectric layer are used in the memory cell 100. Tunneling currents through dielectrics are exponentially related to the tunneling barrier as well as the tunneling distance through the dielectric. Higher barriers and longer tunneling distances are desired to reduce the tunneling leakage through the dielectric. Arrow 1 illustrates the tunneling path of a carrier through the first dielectric 202. Even though this dielectric has a longer tunneling distance, because of its very low tunneling barrier, the tunneling leakage through it is high. Arrow 2 illustrates the tunneling path of a carrier through the second dielectric 206. Even though this dielectric has a higher tunneling barrier, because of its very short tunneling distance, the tunneling leakage through it is high. Arrow 3 illustrates the tunneling path of a carrier through the bilayer dielectric 204, in which the first and second dielectric are placed one after another. In this case, the tunneling barrier is larger than in the case of Arrow 1 and the tunneling distance is longer than in the case of Arrow 2. With a proper choice of thickness and arrangement of dielectrics, this bilayer dielectric leads to a combination of a higher barrier and longer tunneling distance, which can reduce the tunneling leakage current through this stack compared to using a single dielectric barrier alone. In general, one could extend this idea and use a multi-layered dielectric structure to reduce the overall leakage through the stack to a lower value than using any of the dielectrics individually.

FIG. 3 is a graph 300 illustrating leakage current with respect to the voltage of the blocking dielectrics in the non-volatile memory cell, according to an exemplary embodiment of the present disclosure. The graph 300 is included in the description of present disclosure to emphasize the reduction in the leakage current through the top dielectric layers by using a plurality of top dielectric layers (as described for the memory cell 100) in place of a single dielectric layer in the memory cell. The graph 300 illustrates a comparison of the leakage current distribution with respect to the voltage for a single top dielectric layer with a plurality of top dielectric layers. The graph 300 is plotted for leakage current through the top dielectric layers (Y-axis) with respect to the voltage across the top (blocking) dielectrics (X-axis) of the memory cell. An exemplary value of the EOT of the top dielectric layers is 6.43 nm for the purpose of this description only.

The graph 300 includes curve 302, curve 304 and curve 306 The curve 302 represents the leakage current with respect to the applied voltage for the case when only a single layer of ZrO2, which is a lower barrier and higher dielectric constant material, is used as the blocking dielectric. An exemplary value of 1.5 eV for the barrier height and 18.2 for the dielectric constant of ZrO2 is used for the purpose of this description only. The curve 304 represents the leakage current with respect to the applied voltage for the case when only a single layer of Al2O3, which is a higher barrier and lower dielectric constant material, is used as the blocking dielectric. An exemplary value of 2.6 eV for the barrier height and 9.1 for the dielectric constant of Al2O3 is used for the purpose of this description only. The curve 306 represents the leakage current with respect to the applied voltage, of carriers injected from the ZrO2 side, for the case when a bilayer dielectric stack of ZrO2 and Al2O3 is used as the blocking dielectric. With an appropriate choice of thickness and placement of Al2O3 and ZrO2 in the bilayer stack, the overall tunneling leakage through the bilayer blocking dielectric curve 306 can be reduced, compared to using just a single layer of either ZrO2 curve 302, or Al2O3 curve 304 curve, as the blocking dielectric. The choice of ZrO2 or Al2O3 in the example is by no means limiting and to be viewed upon only as an example to demonstrate the advantage of the bilayer blocking dielectrics in reducing the leakage currents through the stack, in comparison with using just single layer dielectrics. Based on the above description, it will be obvious to a person skilled in the art that a desired number of top dielectric layers can be used in the non-volatile memory cell 100. The top dielectric layers 108 may be tuned with the set of attributes to reduce the leakage current through the top dielectric layers 108.

By analyzing the graph 300, it is evident that for a given EOT, there is less leakage current for a given gate voltage in the case when the two layers of top dielectrics are used as compared to either of the single layer of top dielectric. The reduction in the leakage current leads to advantages such as increase in the threshold voltage saturation window for the program and erase operations in the memory cell 100. This is because of the fact that when a Flash cell is programmed or erased by an application of a voltage between the top gate and the active region, there is a tunneling current between the charge storage node and the active region which causes the Cell threshold voltage to increase (program) or decrease (erase) depending on the applied voltage. As the cell programs or erases, the voltage between the top gate and the charge storage node increases and as a result the leakage current through the top dielectric increases. Once the leakage current through the top dielectric starts becoming equal to thte current through the bottom dielectric the programming/erasing of the cell slows down the program/erase threshold voltages saturates. The use of the MBD stack results in a reduction of the leakage current through the top dielectric giving rise to larger program/erase Vt window.

The multi-layer blocking dielectric stack can also be used to improve the overall performance of the non-volatile memory cell. Some of these improvements include but are not limited to, improvement in data retention, improvement in program and erase voltages, improvement in endurance, improvement in disturb characteristics and improvement in scalability.

The foregoing descriptions of specific embodiments of the present disclosure have been presented for purposes of illustration and description. They are not intended to be exhaustive or to limit the disclosure to the precise forms disclosed, and obviously many modifications and variations are possible in light of the above teaching. The embodiments were chosen and described in order to best explain the principles of the disclosure and its practical application, to thereby enable others skilled in the art to best utilize the disclosure and various embodiments with various modifications as are suited to the particular use contemplated. It is understood that various omission and substitutions of equivalents are contemplated as circumstance may suggest or render expedient, but such are intended to cover the application or implementation without departing from the spirit or scope of the claims of the present disclosure.

What is claimed is:

1. A non-volatile memory cell, comprising:
a substrate;
a bottom dielectric layer disposed over the substrate, the bottom dielectric layer providing tunneling migration for charge carriers;
a charge storage node disposed above the bottom dielectric layer;
a plurality of top dielectric layers disposed above the charge storage node, each of the plurality of top dielectric layers capable of being tuned with a set of attributes for reducing a leakage current through the plurality of top dielectric layers; and
a control gate at least partially disposed above the plurality of top dielectric layers.

2. The non-volatile memory cell of claim 1, wherein the set of attributes is at least one of a trapping of electrical charges, an electron barrier height, a hole barrier height and a dielectric constant.

3. The non-volatile memory cell of claim 1, wherein each of the plurality of top dielectric layers has an EOT of less than 10 nanometers.

4. The non-volatile memory cell of claim 1, wherein at least one of the plurality of top dielectric layers has a dielectric constant greater than or equal to about 3.9.

5. The non-volatile memory cell of claim 1, wherein each of the plurality of top dielectric layers is composed of a dielectric material selected from the group consisting of HfO₂, SiO₂, SiOₓN_{y}, SiₓN_{y}, Al₂O₃,HfAlₓO_{y}, H_{f}SiₓO_{y}, ZrO₂, ZrSiₓO_{y}, DyScₓO_{y}, La₂O₃, Y₂O₃, SiO₂, and LaAlₓO_{y}.

6. A non-volatile memory cell, comprising:
a substrate comprising an active area;
a bottom dielectric layer disposed above the active area, the bottom dielectric layer providing tunneling migration for charges to the active area;
a charge storage node disposed above the bottom dielectric layer;
a first top dielectric layer disposed above the charge storage node;
a second top dielectric layer disposed above the first top dielectric layer; and
a control gate at least partially disposed above the second top dielectric layer;
wherein the first top dielectric layer and the second top dielectric layer are capable of being tuned with a set of attributes for reducing the leakage current through the first top dielectric layer and the second top dielectric layer.

7. The non-volatile memory cell of claim 6, wherein the set of attributes is at least one of a trapping of electrical charges, an electron barrier height, a hole barrier height and a dielectric constant.

8. The non-volatile memory cell of claim 6, wherein each of the first top dielectric layer and the second top dielectric layer has an EOT of less than 10 nanometers.

9. The non-volatile memory cell of claim 6, wherein the first top dielectric layer has a dielectric constant greater than or equal to about 3.9. The second top dielectric has a larger dielectric constant than the first top dielectric and a smaller tunneling barrier than the first top dielectric.

10. The non-volatile memory cell of claim 6, wherein the first top dielectric layer and the second top dielectric layer are made of dielectric materials selected from the group consisting of HfO₂, SiO₂, SiOₓN_{y}, SiₓN_{y}, Al₂O₃,HfAlₓO_{y}, H_{f}SiₓO_{y}, ZrO₂, ZrSiₓO_{y}, DyScₓO_{y}, La₂O₃, Y₂O₃, and LaAlₓO_{y}.

11-15. (canceled)

16. A non-volatile memory cell, comprising:
a substrate comprising an active area;
a bottom dielectric layer disposed above the active area, the bottom dielectric layer providing tunneling migration for charges to the active area;
a charge storage node disposed above the bottom dielectric layer;
a first top dielectric layer disposed above the charge storage node;
a second top dielectric layer disposed above the first top dielectric layer;
a third top dielectric layer disposed above the second top dielectric layer; and
a control gate at least partially disposed above the third top dielectric layer;
wherein the first top dielectric layer, the second top dielectric layer and the third top dielectric layer are capable of being tuned with a set of attributes for reducing the leakage current through the first top dielectric layer, the second top dielectric layer and the third top dielectric layer.

17. The non-volatile memory cell of claim 16, wherein the set of attributes is at least one of a trapping of electrical charges, an electron barrier height, a hole barrier height and a dielectric constant.

18. The non-volatile memory cell of claim 16, wherein the second top dielectric layer has a dielectric constant greater than or equal to about 3.9. The first top dielectric has a larger dielectric constant than the second top dielectric and a smaller tunneling barrier than the second top dielectric. The third top dielectric has a larger dielectric constant than the second top dielectric and a smaller tunneling barrier than the second top dielectric.

19. The non-volatile memory cell of claim 16, wherein the first top dielectric layer, the second top dielectric layer and the third top dielectric layer are made of dielectric materials selected from the group consisting of HfO₂, SiO₂, SiOₓN_{y}, SiₓN_{y}, Al₂O₃,HfAlₓO_{y}, H_{f}SiₓO_{y}, ZrO₂, ZrSiₓO_{y}, DyScₓO_{y}, La₂O₃, Y₂O₃, and LaAlₓO_{y}.
